(19) United States
(12) Patent Application Publication
(10) Pub. No.: US 2015/0255317 A1
(43) Pub. Date: Sep. 10, 2015

(54) SEMICONDUCTOR MANUFACTURING EQUIPMENT AND MANUFACTURING METHOD OF SEMICONDUCTOR DEVICE

(71) Applicant: KABUSHIKI KAISHA TOSHIBA, Tokyo (JP)

(72) Inventors: KYOICHI SUGURO, Yokohama Kanagawa (JP); Naoto Miyashita, Kanazawa Ishikawa (JP)

(21) Appl. No.: 14/465,247

(22) Filed: Aug. 21, 2014

(30) Foreign Application Priority Data
Mar. 5, 2014 (JP) 2014-043220

(51) Int. Cl. H01L 21/67; H05B 6/64; H05B 6/70; H01L 21/324; H05B 6/80

(52) U.S. Cl. CPC H01L 21/67115; H01L 21/324; H05B 6/80; H05B 6/707; H05B 6/645

(57) ABSTRACT

A semiconductor manufacturing equipment according to an embodiment includes a support unit, a chamber, a microwave generator, a waveguide, and an auxiliary heating unit. The support unit supports a wafer. The chamber accommodates the support unit therein. The microwave generator generates a microwave. The waveguide is mounted on the chamber to irradiate the microwave to a surface of the wafer. The auxiliary heating unit heats the wafer by an electromagnetic wave with a wavelength shorter than a wavelength of the microwave.

### CROSS REFERENCE TO RELATED APPLICATION(S)

This application is based upon and claims the benefit of priority from the prior Japanese Patent Application No. 2014-043220, filed on Mar. 5, 2014, the entire contents of which are incorporated herein by reference.

### FIELD

Embodiments described herein relate generally to a semiconductor manufacturing equipment and a manufacturing method of a semiconductor device.

### BACKGROUND

Along with downscaling of semiconductor devices, it has been desired to reduce processing temperatures in various semiconductor manufacturing processes. It has been proposed to use a microwave for activating impurities, crystallizing amorphous, forming silicide (a compound of silicon and metal), and the like. However, when a microwave is irradiated to a wafer having a metal layer such as an electrode layer and a wire layer formed therein, a part of the microwave is absorbed or reflected by the metal layer, so that there is a possibility that areas that need to be heated with the microwave may not be heated sufficiently. Therefore, there has been a problem that power consumed for sufficiently heating areas to be heated is increased.

### BRIEF DESCRIPTION OF THE DRAWINGS

FIG. 1 is a schematic configuration diagram showing a semiconductor manufacturing equipment according to a first embodiment;

FIG. 2 is a flowchart showing a manufacturing method of a semiconductor device according to the first embodiment;

FIG. 3 is a schematic configuration diagram of a first chamber of a semiconductor device according to a second embodiment;

FIG. 4 is a schematic configuration diagram of a second chamber of a semiconductor device according to the second embodiment; and

FIG. 5 is a flowchart of a manufacturing method of a semiconductor device according to the second embodiment.

### DETAILED DESCRIPTION

Embodiments will now be explained with reference to the accompanying drawings. The present invention is not limited to the embodiments.

A semiconductor manufacturing equipment according to an embodiment includes a support unit, a chamber, a microwave generator, a waveguide, and an auxiliary heating unit. The support unit supports a wafer. The chamber accommodates the support unit therein. The microwave generator generates a microwave. The waveguide is mounted on the chamber to irradiate the microwave to a surface of the wafer. The auxiliary heating unit heats the wafer by an electromagnetic wave with a wavelength shorter than a wavelength of the microwave.

### First Embodiment

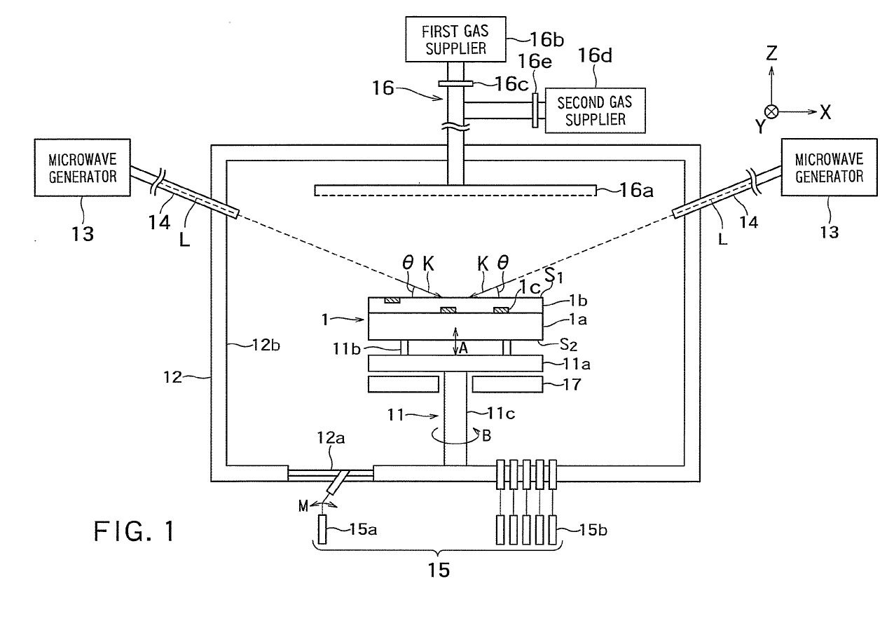

FIG. 1 is a schematic configuration diagram showing a semiconductor manufacturing equipment according to a first embodiment. A semiconductor manufacturing equipment shown in FIG. 1 includes a support unit 11, a chamber 12, a microwave generator 13, a waveguide 14, a thermometer 15, a cooler 16, and an auxiliary heating unit 17.

The support unit 11 is a mechanism for supporting the wafer 1 and includes a quartz susceptor 11a, a plurality of support pins 11b, and a rotating shaft 11c. The quartz susceptor 11a is formed of quartz that is a transparent material. The support pins 11b protrude from a front surface of the quartz susceptor 11a and can move the wafer 1 in a vertical direction as indicated by an arrow A. The rotating shaft 11c is mounted on a back surface of the quartz susceptor 11a and can cause the wafer 1 to rotate within a horizontal plane as indicated by an arrow B.

The wafer 1 shown in FIG. 1 includes a substrate 1a, one or more processing target layers 1b formed on the substrate 1a, and one or more metal layers is included in the processing target layer 1b. The substrate 1a is a semiconductor substrate such as a silicon substrate, a GaN substrate, a Si substrate having GaN formed thereon, a substrate, and a Si substrate having SiC formed thereon. For example, the processing target layer 1b is an interlayer dielectric film, a shallow trench isolation insulation film, an electrode layer, or a wire layer. The metal layer is 1c an electrode layer including metal electrodes, a wire layer including metal wires, or the like.

Reference character S₁ denotes a front surface of the wafer 1, that is, a surface of the wafer 1 on a side of a processing target layer 1b. Reference character S₂ denotes a back surface of the wafer 1, that is, a surface of the wafer 1 on a side of the substrate 1a. The wafer 1 according to the first embodiment is installed on the support unit 11 with the front surface S₁ facing the top and the back surface S₂ facing the bottom. The support unit 11 according to the first embodiment supports the back surface S₂ of the wafer 1.

FIG. 1 shows an X direction and a Y direction that are parallel to the front surface S₁ and the back surface S₂ of the wafer 1 and are vertical to each other, and a Z direction that is vertical to the front surface. S₁ and the back surface S₂ of the wafer 1. In the present specification, a +Z direction is designated as an upward direction and a −Z direction is designated as a downward direction. For example, in the positional relationship between the substrate 1a and the processing target layer 1b, the substrate 1a is under the processing target layer 1b.

The chamber 12 accommodates the support unit 11 therein. In FIG. 1, the wafer 1 having been carried in the chamber 12 is installed on the support unit 11. For example, the chamber 12 is formed of a material such as Al, Al alloy, or SUS (stainless steel).

The chamber 12 includes a window 12a for measuring the temperature of the wafer 1 on the support unit 11. The window 12a is formed of a transparent material such as quartz or sapphire.

An inner wall surface 12b of the chamber 12 is coated with a non-metallic material having a thickness of approximately 1 to 10 μm. An insulating material or a material with low conductivity is used as the non-metallic material, and examples of the non-metallic material include silica (silicon oxide) and polyimide. It has been confirmed that metal contamination of the wafer 1 can be prevented by coating the non-metallic material.

The microwave generator 13 generates a microwave. The frequency of microwave can be any value within the frequency range as follows. The microwave generator 13 according to the first embodiment generates a microwave having a frequency band of 2.45 to 30 GHz, preferably a microwave having a frequency band equal to or higher than 5.80 GHz. For example, the frequency of the microwave can be set to 5.80 GHz to 14 GHz in view of the manufacturing costs and reliability of the microwave generator 13.

The waveguide 14 is mounted on the chamber 12 to emit a microwave that is generated by the microwave generator 13 in a K direction, and irradiates the microwave emitted in the K direction to the front surface S₁ of the wafer 1. In FIG. 1, the K direction is a direction that is not vertical to the front surface S₁ and the back surface S₂ of the wafer 1. Therefore, the K direction is not parallel to the Z direction. The K direction can be also a direction vertical to the front surface S₁ and the back surface S₂ of the wafer 1.

The number of the waveguides 14, the position where the waveguide 14 is mounted, and the mounting method thereof can be arbitrarily designed. For example, the waveguide 14 is preferably provided in plural to be capable of uniformly irradiating a microwave, to the front surface S₁ of the wafer 1. Furthermore, as shown in FIG. 1, the waveguide 14 can be mounted on a side surface of the chamber 12 or on a top surface thereof. Further, the waveguide 14 can be directly mounted on the chamber 12, or can be indirectly mounted on the chamber 12 via other members and the like.

Reference character L denotes a central axis of the waveguide 14. The central axis L according to the first embodiment is set to be parallel to the K direction. As a result, the waveguide 14 according to the first embodiment emits a microwave in the K direction. Reference character θ denotes an angle of the K direction with respect to the front surface S₁ and the back surface S₂ of the wafer 1. The angle θ according to the first embodiment is 0°≦θ≦90°, and is preferably less than 90°.

The thermometer 15 is a radiation thermometer (a pyrometer) that irradiates infrared light to the back surface S₂ of the wafer 1 and measures the intensity of reflected light, thereby measuring the temperature of the wafer 1. A thermometer 15a according to the first embodiment measures an electromagnetic wave (light) radiated from the wafer 1 via the window 12a, thereby measuring the temperature of the wafer 1. When infrared light cannot be irradiated to the back surface S₂ of the wafer 1 as the infrared light is blocked by other constituent elements between the thermometer 15a and the wafer 1, a distal end of the thermometer 15a connected thereto by an optical fiber is moved in a direction of an arrow M in FIG. 1 and is positioned to be capable of irradiating infrared light. Thermometers 15b are arranged to be capable of measuring the temperature of the wafer 1 at a plurality of positions with radially different distances from the center of the wafer 1. For example, temperature measurement results by the thermometer 15 are used for controlling the position of the support pin 11b, the rotation of the rotating shaft 11c, operations of the microwave generator 15 and the cooler 16, and the like.

The cooler 16 is a gas supplier for cooling the wafer 1, performing processes, and the like. The cooler 16 uniformly supplies inert gas such as Ar, Ne, He, Xe, and N₂ from a first gas supplier 16b and a second gas supplier 16d via a nozzle 16a having a plurality of openings like a shower to the front surface S₁ of the wafer 1. Paths between the nozzle 16a and the first gas supplier 16b and the second gas supplier 16d are opened or closed by valves 16c and 16e. In FIG. 1, while the semiconductor manufacturing equipment includes one cooler 16, the semiconductor manufacturing equipment can be also configured to include a plurality of the coolers 16.

The auxiliary heating unit 17 generates an electromagnetic wave with a wavelength shorter than that of the microwave generated by the microwave generator 13, and irradiates the electromagnetic wave to the wafer 1, thereby heating the wafer 1. The microwave is an electromagnetic wave having a wavelength of 100 μm to 1 m (having a frequency of 300 MHz to 3 THz). Therefore, examples of the electromagnetic wave with a wavelength shorter than that of a microwave include light such as infrared light, visible light, and ultraviolet light. The auxiliary heating unit 17 shown in FIG. 1 is a hot plate arranged on a back surface of the quartz susceptor 11a, and heats the wafer 1 with far-infrared light. As the auxiliary heating unit 17, a halogen lamp, an arc lamp, a laser device, and the like can be used instead of a hot plate. The auxiliary heating unit 17 is arranged at an appropriate position according to a unit to be used.

As explained above, according to the semiconductor manufacturing equipment of the first embodiment, the wafer 1 can be heated with a microwave irradiated from the waveguide 14 and an electromagnetic wave that is irradiated from the auxiliary heating unit 17 and has a wavelength shorter than that of the microwave. Therefore, at the time of heating the wafer 1 to a desired temperature, as the wafer 1 is also heated by the auxiliary heating unit 17, output of the microwave for heating the wafer 1 can be reduced and thus consumption power can be reduced.

A conventional and general semiconductor manufacturing equipment emits a microwave in the −Z direction and irradiates the microwave emitted in the −Z direction to the front surface S₁ of the wafer 1. That is, the microwave is irradiated in a direction vertical to the front surface S₁ of the wafer 1. Therefore, when a microwave is reflected by the front surface S₁ of the wafer 1, the microwave is reflected mainly in the +Z direction. The microwave reflected in the +Z direction reaches an upper part of the chamber 12. Generally, many devices are arranged in the upper part of the chamber 12 and thus a microwave having reached the upper part of the chamber 12 is reflected in various directions. Therefore, the most part of the microwave having reached the upper part of the chamber 12 is not irradiated again to the wafer 1.

On the other hand, the semiconductor manufacturing equipment of the first embodiment emits a microwave in the K direction and irradiates the microwave emitted in the K direction to the front surface S₁ of the wafer 1. The K direction is set to be a direction that is not vertical to the front surface S₁ of the wafer 1, so that the microwave is irradiated in the direction that is not vertical to the front surface S₁ of the wafer 1. In this case, the microwave reflected by the front surface S₁ of the wafer 1 mainly reaches a side surface part of the chamber 12. Generally, only few devices are arranged in the side surface part of the chamber 12 and thus the most part of the microwave having reached the side surface part of the chamber 12 is repeatedly reflected by the inner wall surface 12b of the chamber 12. Therefore, the most part of the microwave having reached the side surface part of the chamber 12 can be irradiated again to the wafer 1.

In this way, according to the first embodiment, even when the wafer 1 includes the metal layer 1c, by repeatedly irradiating the same microwave to the wafer 1, the wafer 1 can be heated with less consumption power. Further, a microwave is irradiated to various areas in the wafer 1 from various directions, so that the wafer 1 can be uniformly heated.

The position, angle, and shape of the waveguide 14 according to the first embodiment are desirably designed such that a microwave emitted from each waveguide 14 is not returned to the same waveguide 14 or other waveguides 14.

Furthermore, in a conventional and general semiconductor manufacturing equipment, the inner wall surface 12b of the chamber 12 is not coated with a non-metallic material. Therefore, when the wafer 1 is heated, metal atoms constituting the chamber 12 such as Al may be detached from the inner wall surface 12b, floated in the chamber 12, and then attached to the wafer 1. For example, when a conventional general semiconductor manufacturing equipment performs microwave annealing on the wafer 1 at a temperature of 600° C. to 800° C., there is a case where metal contamination in the order of 1E10 cm⁻² is detected on the front surface S₁ of the wafer 1. Such metal contamination causes defects called “white defect” in a CMOS image sensor or a CCD image sensor.

On the other hand, in the semiconductor manufacturing equipment according to the first embodiment, the inner wall surface 12b of the chamber 12 is coated with a non-metallic material. Therefore, when the wafer 1 is heated, metal atoms constituting the chamber 12 such as Al are prevented from being detached from the inner wall surface 12b. Therefore, metal contamination of the wafer 1 can be suppressed. For example, when the semiconductor manufacturing equipment according to the first embodiment performs microwave annealing on the wafer 1 at a temperature of 600° C. to 800° C., metal contamination on the front surface S₁ of the wafer 1 can be reduced to a level of 1E8 cm⁻² or less (a level undetectable by ICP-MASS). Accordingly, generation of white defect in a CMOS image sensor or a CCD image sensor can be suppressed significantly.

The semiconductor manufacturing equipment according to the first embodiment can be used for an arbitrary heating process in a semiconductor device. For example, the semiconductor manufacturing equipment can be used for heating processes for crystallizing amorphous materials and growing seed crystals, recovering crystal defects on semiconductor patterns, reducing the resistance of suicide (a compound of metal and silicon), a W plug, a Cu wire, and the like, reducing contact resistance, improving the quality of insulation films, and reducing the interface state and fixed charges in transistors.

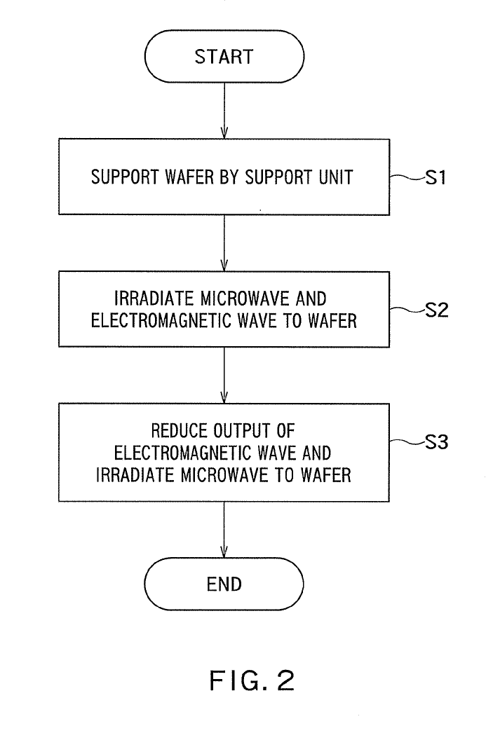

Next, a manufacturing method of a semiconductor device using the semiconductor manufacturing equipment shown in FIG. 1 is explained with reference to FIG. 2. FIG. 2 is a flowchart showing a manufacturing method of a semiconductor device according to the first embodiment. A method of forming polycrystalline Si from amorphous Si formed as the processing target layer 1b of the wafer 1 by a heating process is explained below. Amorphous Si is a non-crystalline silicon compound, and polycrystalline Si is a crystalline silicon compound.

First, the wafer 1 having an amorphous Si film formed therein as the processing target layer 1b is carried in the chamber 1, and the wafer 1 is installed on the support unit (Step S1). At this time, the wafer 1 is installed on the support unit 11 with the front surface S₁ facing up and the back surface S₂ facing down. Note that the wafer 1 can be also installed on the support unit 11 with the front surface S₁ facing down and the back surface S₂ facing up.

Next, an electromagnetic wave such as light with a wavelength shorter than that of a microwave such as far-infrared light is irradiated to the front surface S₁ of the wafer 1 by the auxiliary heating unit 17 so as to heat the wafer 1 at a temperature of 200° C. to 400° C. Simultaneously with the heating by the auxiliary heating unit 17, a microwave is generated by the microwave generator 13 and the generated microwave is emitted from the waveguide 14 in the K direction. With this configuration, a microwave is irradiated to the front surface S₁ of the wafer 1 and the wafer 1 is annealed with the heat of the microwave (Step S2). Output of the microwave is set such that, with heating of the microwave and the electromagnetic wave such as light, the temperature of the wafer 1 is equal to or higher than 700° C. When the wafer 1 is installed with the back surface S₂ facing up, the microwave is irradiated to the back surface S₂.

With the above process, seed crystals are formed in amorphous Si formed as the processing target layer 1b of the wafer 1. The heating time of the wafer 1 is set according to the thickness of the processing target layer 1b. For example, when the thickness of the processing target layer 1b is equal to or less than 10 nm, the heating time is 10 seconds to 60 seconds.

After seed crystals are formed in amorphous Si, output of an electromagnetic wave by the auxiliary heating unit 17 is reduced, and irradiation of a microwave is continued (Step S3). In this case, reduction of output of an electromagnetic wave includes ending of heating by the auxiliary heating unit 17, that is, reducing the output of the electromagnetic wave to 0 (zero).

By irradiating a microwave to the wafer 1 after seed crystals are formed, torsional oscillation occurs in electronic polarization due to an irregular atomic arrangement in amorphous Si, so that covalent bonds of Si are recombined and positions thereof are slightly moved. Accordingly, a Si crystal is grown from a seed crystal as a starting point at a high speed, and the size of a seed crystal is increased. Therefore, polycrystalline Si can be formed in a short time. When the thickness of the processing target layer 1b is equal to or less than 10 nm, with irradiation of a microwave, for example, a Si crystal can be grown to a Si crystal having a grain diameter of 300 nm or more in a direction parallel to the front surface S₁ of the wafer 1.

At this time, it is possible to control a seed crystal density by reducing output of an electromagnetic wave by the auxiliary heating unit 17. When heating by the auxiliary heating unit 17 at Step S2 is continued, the seed crystal density is increased, so that there is a possibility that growth of the respective crystals is blocked. However, as explained above, in a seed crystal growing process at Step S3, by reducing the output of the electromagnetic wave by the auxiliary heating unit 17, the seed crystal density can be controlled to a desired seed crystal density.

During the processes at Steps S2 and S3, it is possible to rotate the wafer 1 by rotating the rotating shaft 11c. With this configuration, the wafer 1 can be heated more uniformly. During the processes at Steps S2 and S3, the temperature of the wafer 1 can be measured by the thermometer 15 and the wafer 1 can be cooled by the cooler 16.

Because a conventional semiconductor manufacturing equipment does not include an auxiliary heating unit, in a heating process of forming a seed crystal in amorphous Si, the wafer 1 needs to be heated equal to or higher than 700° C. only by a microwave, so that output of the microwave required for heating is increased and consumption power is also increased. However, according to the first embodiment, heating with a microwave and heating with an electromagnetic wave such as light with a wavelength shorter than that of a microwave are performed at the same time, thereby reducing the power consumed by heating with a microwave.

By irradiating a microwave in a direction that is not vertical to the front surface S₁ of the wafer 1, the wafer 1 can be uniformly heated. Furthermore, by using a semiconductor manufacturing equipment in which the inner wall surface 12b of the chamber 12 is coated with a non-metallic material, so that metal contamination of the wafer 1 in the heating processes at Steps S2 and S3 can be suppressed.

### Second Embodiment

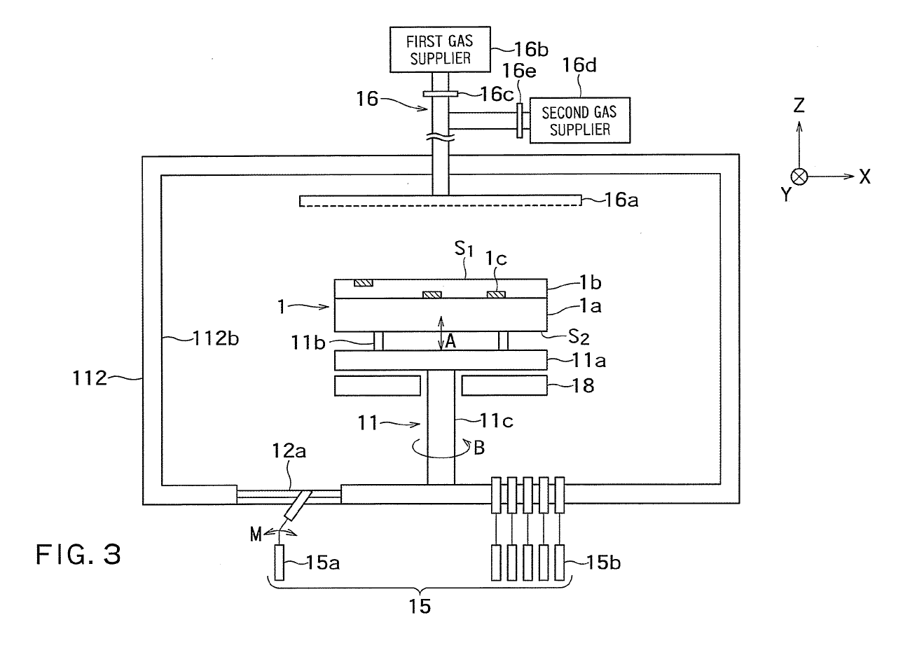

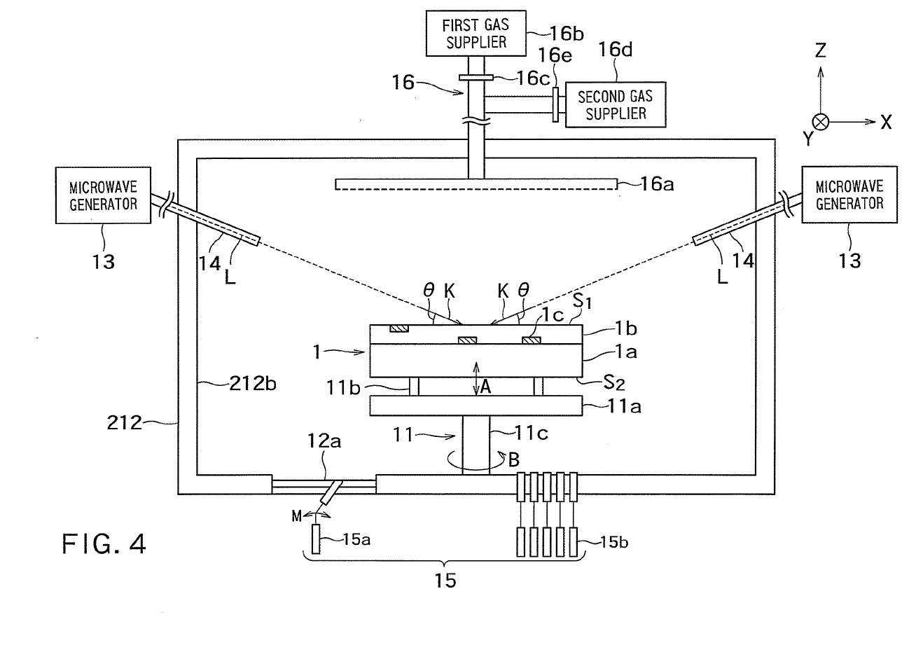

Next, a semiconductor manufacturing equipment according to a second embodiment is explained with reference to FIGS. 3 and 4. The semiconductor manufacturing equipment according to the second embodiment includes a first chamber 112 and a second chamber 212. FIG. 3 is a schematic configuration diagram of the first chamber 112, and FIG. 4 is a schematic configuration diagram of the second chamber 212.

As shown in FIG. 3, the first chamber 112 includes the support unit 11, the thermometer 15, the cooler 16, and a heating unit 18. Configurations of the support unit 11, the thermometer 15, and the cooler 16 are identical to those of the semiconductor manufacturing equipment according to the first embodiment.

The first chamber 112 accommodates the support unit 11 therein. In FIG. 3, the wafer 1 having been carried in the first chamber 112 is installed on the support unit 11. For example, the first chamber 112 is formed of a material such as Al, Al alloy, or SUS (stainless steel).

The first chamber 112 includes the window 12a for measuring the temperature of the wafer 1 on the support unit 11. The window 12a is formed of a transparent material such as quartz or sapphire.

An inner wall surface 112b of the first chamber 112 is coated with a non-metallic material having a thickness of approximately 1 to 10 μm. An insulating material or a material with low conductivity is used as the non-metallic material, and examples of the non-metallic material include silica (silicon oxide) and polyimide.

The heating unit 18 (first heating unit) generates an electromagnetic wave such as light with a wavelength shorter than that of a microwave and irradiates the electromagnetic wave to the wafer 1, thereby heating the wafer 1 to, for example, a temperature of 700° C. As the heating unit 18, a halogen lamp, an arc lamp, a laser device, and the like can be used. When the laser device is used, a laser wavelength is selected according to the thickness of the processing target layer 1b of the wafer 1 serving as a heating target. For example, when the thickness of the processing target layer 1b is equal to or less than 100 nm, an excimer laser using XeCl or KrF is used. When the thickness is 100 nm to 1 μm, a solid laser using YAG or the like is used. When the thickness is equal to or larger than 1 μm, a CO₂ laser is used. The heating unit 18 is arranged at an appropriate position according to a unit to be used

As shown in FIG. 4, the second chamber 212 includes the support unit 11, the microwave generator 13 and the waveguide 14 (second heating unit), the thermometer 15, and the cooler 16. Configurations of the support unit 11, the microwave generator 13, the waveguide 14, the thermometer 15, and the cooler 16 are identical to those in the semiconductor manufacturing equipment according to the first embodiment.

The second chamber 212 accommodates the support unit 11 therein. In FIG. 4, the wafer 1 having been carried in the first chamber 112 is installed on the support unit 11. For example, the second chamber 112 is formed of a material such as Al, Al alloy, or SUS (stainless steel).

The second chamber 212 includes the window 12a for measuring the temperature of the wafer 1 on the support unit 11. The window 12a is formed of a transparent material such as quartz or sapphire.

An inner wall surface 212b of the second chamber 212 is coated with a non-metallic material having a thickness of approximately 1 to 10 μm. An insulating material or a material with low conductivity is used as the non-metallic material, and examples of the non-metallic material include silica (silicon oxide) and polyimide.

As explained above, according to the second embodiment, inner wall surfaces of the first chamber 112 and the second chamber 212 are coated with a non-metallic material, and thus metal contamination at the time of heating the wafer 1 can be suppressed.

The first chamber 112 and the second chamber 212 can be incorporated in a single device, or can be constituted as respectively individual semiconductor manufacturing equipments.

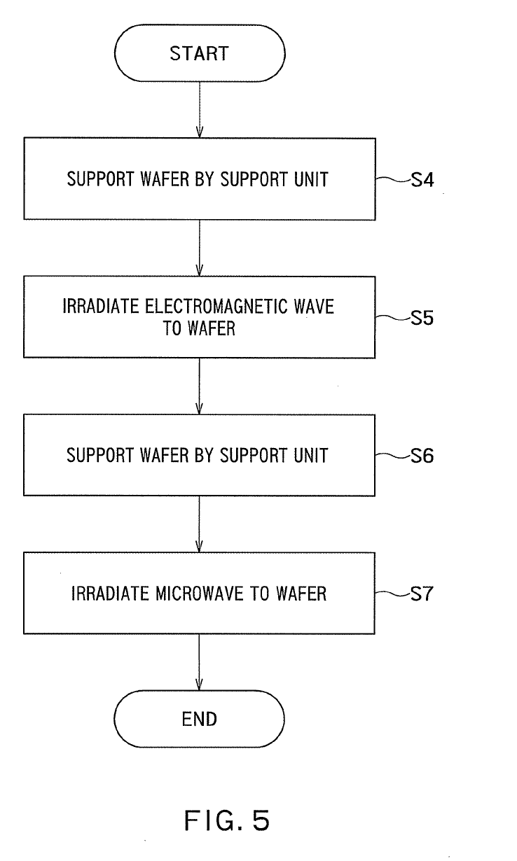

Next, a manufacturing method of a semiconductor device using the semiconductor manufacturing equipment according to the second embodiment is explained with reference to FIG. 5. FIG. 5 is a flowchart of a manufacturing method of a semiconductor device according to the second embodiment. A method of forming polycrystalline Si from amorphous Si formed as the processing target layer 1b of the wafer 1 is explained below.

First, the wafer 1 having an amorphous Si film formed therein as the processing target layer 1b is carried in the first chamber 112 and installed on the support unit 11 (Step S4). At this time, the wafer 1 is installed on the support unit 11 with the front surface S₁ facing up and the back surface S₂ facing down.

Next, an electromagnetic wave such as light is irradiated to the wafer 1 by the heating unit 18, thereby heating the wafer 1 to a temperature of 700° C. (Step S5). With this process, seed crystals are formed in amorphous Si formed as the processing target layer 1b of the wafer 1. The heating time of the wafer 1 is set according to the thickness of the processing target layer 1b.

After seed crystals are formed in amorphous Si, the wafer 1 is carried in the second chamber 112 and installed on the support unit 11 (Step S6). At this time, the wafer 1 is installed on the support unit 11 with the front surface S₁ facing up and the back surface S₂ facing down.

Next, a microwave is generated by the microwave generator 13 and the generated microwave is emitted from the waveguide 14 in the K direction. With this configuration, the microwave is irradiated to the front surface S₁ of the wafer 1 and the wafer 1 is annealed with heat of the microwave (Step S7).

By irradiating a microwave to the wafer 1 after seed crystals are formed, torsional oscillation occurs in electronic polarization due to an irregular atomic arrangement present in amorphous Si, so that covalent bonds of Si are recombined and positions thereof are slightly moved. Accordingly, a Si crystal is grown from a seed crystal as a starting point at a high speed, and the size of a seed crystal is increased. Therefore, polycrystalline Si can be formed in a short time. When the thickness of the processing target layer 1b is equal to or less than 10 nm, with irradiation of a microwave, for example, a Si crystal can be grown to have a grain diameter of 300 nm or more in a direction parallel to the front surface S₁ of the wafer 1.

As explained above, according to the manufacturing method of a semiconductor device of the second embodiment, irradiation of a microwave is not used in a process of forming a seed crystal of amorphous Si but used only in a seed crystal growing process. Accordingly, output of a required microwave can be reduced and power consumed for generating a microwave can be also reduced.

Furthermore, by irradiating a microwave in a direction that is not vertical to the front surface S₁ of the wafer 1, the wafer 1 can be heated uniformly. Further, inner wall surfaces of the first chamber 112 and the second chamber 212 are coated with a non-metallic material, and thus metal contamination in the heating processes at Steps S5 and S7 can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing equipment comprising:
a support unit supporting a wafer;
a chamber accommodating the support unit therein;
a microwave generator generating a microwave;
a waveguide mounted on the chamber to irradiate the microwave to a front surface or a back surface of the wafer; and
an auxiliary heating unit heating the wafer by an electromagnetic wave with a wavelength shorter than a wavelength of the microwave.

2. The equipment of claim 1, wherein the auxiliary heating unit is any one of a hot plate, a halogen lamp, an arc lamp, and a laser device.

3. The equipment of claim 1, wherein the waveguide irradiates the microwave in a direction that is not vertical to the front surface or the back surface of the wafer.

4. The equipment of claim 1, wherein an inner wall of the chamber is coated with a non-metallic material.

5. The equipment of claim 1, wherein a frequency of the microwave is equal to or higher than 2.45 GHz and equal to or less than 30 GHz.

6. The equipment of claim 1, wherein a frequency of the microwave is equal to or higher than 5.8 GHz and equal to or less than 14 GHz.

7. The equipment of claim 1, wherein a wavelength of the electromagnetic wave is equal to or higher than 100 μm and equal to or less than 1 m.

8. The equipment of claim 1, wherein the electromagnetic wave is any one of far-infrared light, infrared light, visible light, and ultraviolet light.

9. The equipment of claim 1, wherein a plurality of the waveguides are mounted on the chamber.

10. The equipment of claim 4, wherein the non-metallic material is an insulating material or a low conductive material.

11. The equipment of claim 4, wherein the non-metallic material is silica or polyimide.

12. The equipment of claim 1, further comprising a cooler supplying inert gas to the chamber.

13. The equipment of claim 12, wherein the inert gas is any one of Ar, Ne, He, Xe, or N₂.

14. The equipment of claim 1, further comprising a thermometer measuring a temperature of the wafer supported by the support unit.

15. The equipment of claim 14, wherein the thermometer is a radiation thermometer.

16. A manufacturing method of a semiconductor device comprising:
installing a wafer on a support unit in a chamber; and
heating the wafer by irradiating a microwave from a waveguide mounted on the chamber to a front surface or a back surface of the wafer, the microwave is generated by a microwave generator, and irradiating an electromagnetic wave with a wavelength shorter than a wavelength of the microwave from an auxiliary heating unit to the wafer.

17. The method of claim 16, wherein the wafer is heated to a temperature of equal to or higher than 700° C. with the microwave and the electromagnetic wave.

18. The method of claim 16, wherein after the wafer is heated with the microwave and the electromagnetic wave, output of the electromagnetic wave is reduced and irradiation of the microwave is continued.

19. The method of claim 16, wherein the auxiliary heating unit is any one of a hot plate, a halogen lamp, an arc lamp, and a laser device.

20. A manufacturing method of a semiconductor device comprising:
installing a wafer in a chamber; and
irradiating an electromagnetic wave with a wavelength shorter than a wavelength of a microwave, the electromagnetic wave is generated by a first heating unit provided in the chamber, and then irradiating the microwave to a front surface of the wafer, the microwave is generated by a second heating unit.
